(19) United States
(12) Patent Application Publication
(10) Pub. No.: US 2019/0332019 A1
(43) Pub. Date: Oct. 31, 2019

(54) METHOD FOR ADDING ASSIST FEATURES

(71) Applicant: SHANGHAI IC R&D CENTER CO., LTD., Shanghai (CN)

(72) Inventor: Hongmei HU, Shanghai (CN)

(21) Appl. No.: 16/475,116

(22) PCT Filed: Nov. 23, 2017
(86) PCT No.: PCT/CN2017/112496

§ 371 Date: Jun. 30, 2019

(30) Foreign Application Priority Data
Dec. 30, 2016 (CN) 201611259536.0

(51) Int. Cl. G03F 7/20; G03F 1/36

(52) U.S. Cl. CPC G03F 7/70441; G03F 1/36

(57) ABSTRACT

A method for adding Assist Feature comprises providing target patterns for OPC, selecting a rule in which only one Assist Feature can be added based on a Base AF rule, and establishing an Extra Assist Feature rule; making a global size-up of the target patterns, so that all sides of the target patterns extend outwards by a distance A; subtracting the distance value between the corresponding sides of the target patterns formatted under the Extra Assist Feature rule by a distance 2A based on the Extra Assist Feature rule; and carrying out the corresponding adjustment on other parameters which are affected by the overall sizing of the target patterns formatted under the Extra Assist Feature rule based on a distance A; operating the Extra Assist Feature rule to generate a first Assist Feature; executing the Base AF rule on the target patterns, generating a second Assist Feature by using the first Assist Feature as a newly-added reference feature, and superimposing the first Assist Feature, the second Assist Feature and the existing Assist Feature to form a final Assist Feature.

### CROSS-REFERENCE TO RELATED APPLICATION

This application claims priority of International Patent Application Serial No. PCT/CN2017/112496, filed Nov. 23, 2017, which is related to and claims priority of Chinese patent application Serial No. 201611259536.0, filed Dec. 30, 2016. The entirety of each of the above-mentioned patent applications is hereby incorporated herein by reference and made a part of this specification.

### TECHNICAL FIELD

The present disclosure relates to the technical field of integrated circuits, in particular to a method for adding Assist Features.

### BACKGROUND

In the dark field process, the light intensity obtained by the contact/hole pattern is weak, and the image contrast is poor. With the decrease of the line width, the Mask Error Factor (MEF) of the contact/hole layer increases significantly, which leads to a significant change of the line width on wafer level due to the small fluctuation of the size on Mask level, at the same time, various fluctuations can occur in the process conditions of the semiconductor, such as the fluctuation of focus, the fluctuation of exposure energy and the like can cause the fluctuation of the line width in the lithography process. Therefore, in order to ensure the yield, the resolution and process window of contact/hole layer should be improved.

At present, Assist Feature (AF) may be inserted around the contact/hole, which includes a rule-based AF (RBAF) and a model-based AF (MBAF), so that the spatial frequency and image contrast of the contact/hole are improved, and the resolution and process window of the contact/hole are improved. The principle of the MBAF is to add AF based on a model, and the operation time of the MBAF is long, while the RBAF is to add AF based on a set of rules, which includes the addition of the side AF and the corner AF.

The AF rule is formulated based on a large amount of the measurement data collected on the silicon wafer relative to sets of Assist Feature, the line width, the patterns (including 1D and 2D patterns) and the like. According to the verified AF rule, in an optical proximity correction (OPC) process, the AF is added to a target pattern which needs to be subjected to the OPC correction, this is commonly referred to as RBAF. The RBAF includes side bar Assist Features and corner bar Assist Features, the main parameter of the side bar is provided with the side bar width (SBW)/the distance between the side to main (S2M)/the distance between the side to side (S2S); and the main parameters of the corner AF is provided with the side bar width (SBW)/the distance between the side to main (S2M), as shown in FIG. 1. According to the distance between the corresponding sides of the adjacent patterns (for example, the contact/hole patterns), with reference to the AF rule, to determine the AF parameter of the region between the corresponding sides of the adjacent pattern for adding AF. According to the distance, one, or two, more than two AF can be added between the two contact/holes.

For some contact/hole patterns, when a region where the overlap edge length between the corresponding sides of the pattern is short and limited by the parameter of the minimum length of the AF, the parameter of the S2M and the other parameters, for conventional RBAF, the AF will not be added in the region. The final addition result of the AF in a region A is the slanted graph, as shown in FIG. 2.

### SUMMARY

The present disclosure aims to overcome the defects in the prior art, and to provide a method for adding Assist Feature, which can realize the addition of the Assist Feature under the condition that the overlap edge length between the corresponding sides of the patterns in the OPC target patterns is short.

In order to achieve the aims, the present disclosure provides a method for adding Assist Features, which comprises the following steps:

Step 01, providing target patterns for OPC, selecting a rule in which only one Assist Feature can be added based on a Base AF rule, and establishing an Extra Assist Feature rule; wherein the target patterns may already have Assist Feature;

Step 02, making a global size-up of the target patterns, so that all sides of the target patterns extend outwards by a distance A; wherein the distance A is a non-negative number, and the unit of the distance A is a unit of length;

Step 03, subtracting the distance value between the corresponding sides of the target patterns formatted under the Extra Assist Feature rule by a distance 2A based on the Extra Assist Feature rule; and carrying out the corresponding adjustment on other parameters which are affected by the overall sizing of the target patterns formatted under the Extra Assist Feature rule based on a distance A;

Step 04, operating the Extra Assist Feature rule to generate a first Assist Feature; Step 05, executing the Base AF rule on the target patterns, generating a second Assist Feature by using the first Assist Feature as a newly added reference feature, and superimposing the first Assist Feature, the second Assist Feature and the existing Assist Feature to form a final Assist Feature.

Preferably, in the Step 02, the distance A is less than ½ of the minimum space allowed by the target patterns.

Preferably, the Assist Features in the Rule-based Assist Feature and the Assist Features in the Extra Assist Feature rule are side bar Assist Features.

Preferably, in the Step 01 and before the Extra Assist Feature rule is established, the method further includes: establishing an initial Rule-based Assist Feature on the target patterns based on the Base AF rule; in step 05, the method further comprises: executing the Rule-based Assist Feature on the target patterns, generating a second Assist Feature by using the first Assist Feature, the initial Rule-based Assist Feature, the original input Assist Feature and the original input reference pattern as reference pattern; the final Assist Feature is composed of the first Assist Feature, the second Assist Feature, the initial Rule-based Assist Feature and the original input Assist Feature.

Preferably, the initial Rule-based Assist Feature comprises side bar Assist Features and corner bar Assist Features.

Preferably, the OPC target patterns are contact/hole patterns.

Preferably, the Assist Feature is sub-resolution pattern.

Preferably, the method further comprises a Step between the Step 04 and the Step 05, the Step is, replacing the OPC target after global sizing with the target patterns in Step 01.

In the method for adding Assist Features according to the present disclosure, an Extra Assist Feature rule is established and the size of the contact/hole target patterns in the target patterns is globally amplified. The present disclosure aims to overcome the problem that the AF cannot be added through a conventional RBAF method when the overlap edge length between the corresponding sides of the contact/hole patterns is short. Therefore, comparing with the conventional RBAF method, the method of the present disclosure has the advantage that the Assist Feature is more possibly and reasonably to be added into the OPC target patterns which includes contact/hole patterns under the condition of maintaining the Base AF rule, so that the quality and the process window of the OPC target patterns are effectively improved.

### BRIEF DESCRIPTION OF THE DRAWINGS

For more clearly understanding of the objects, features and advantages of the present disclosure, the preferred embodiments of the present disclosure will be described in detail below with reference to the accompanying drawings, wherein:

FIG. 1 is a parameter schematic diagram of the RBAF

FIG. 2 is a schematic diagram of a conventional Assist Feature corresponding to that when the overlap edge length between the corresponding sides of the contact/hole patterns in target patterns is short

FIG. 3 is a flow diagram of method for adding Assist Features according to a preferred embodiment of the present disclosure

FIG. 4 is a schematic diagram of the integral amplification of the target patterns according to a preferred embodiment of the present disclosure

FIG. 5 is a schematic diagram for forming a first Assist Feature after the integral amplification of the target patterns according to a preferred embodiment of the present disclosure

FIG. 6 is a schematic diagram for restoring the amplified target patterns in the target patterns to initial target patterns after generating a first Assist Feature according to one preferred embodiment of the present disclosure

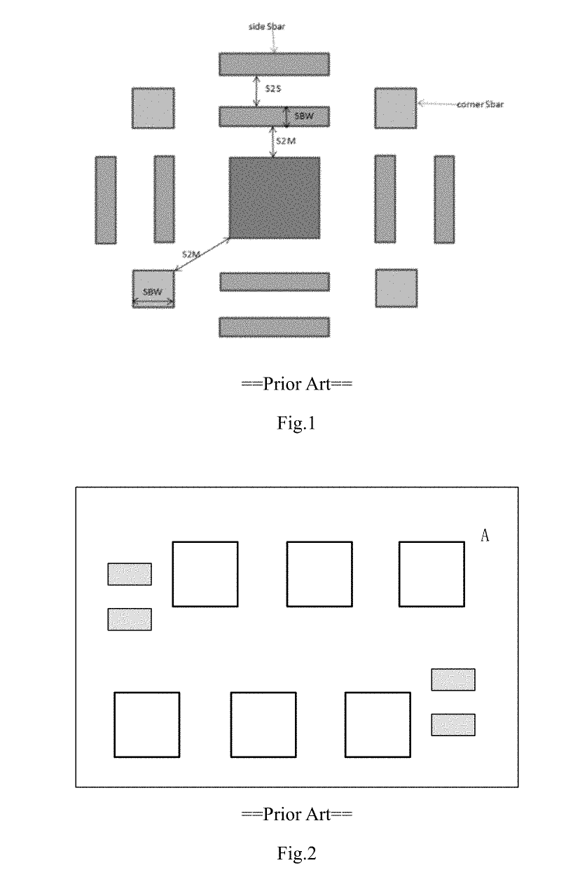

### DETAILED DESCRIPTION

In order to make the contents of the present disclosure more comprehensible, the contents of the present disclosure are further described below in conjunction with the description of the specification. Of course, the present disclosure is not limited to this specific embodiment, the general replacement well known by those skilled in the art is also contemplated within the protection scope of the present disclosure.

In the present disclosure, according to a Base Assist Feature rule, hereinafter referred to as the Base AF rule, an Extra Assist Feature rule is formulated, hereinafter referred to as an Extra AF rule. The Extra AF rule only contains a rule information that only one AF can be added to the Base AF rule.

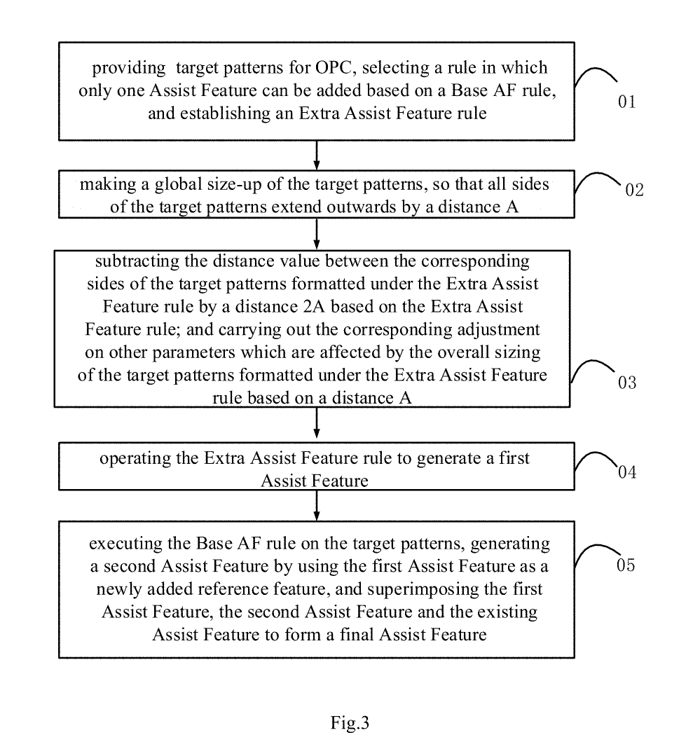

The present disclosure described in further detail below with reference to FIGS. 3-6 and specific embodiments. It should be noted that the Figures are in a very simplified form, and the non-precise proportion is used, and is only used for conveniently and clearly achieving the purpose of assisting in describing the embodiment of the present disclosure.

Referring to FIG. 3, a method for adding Assist Features according to an embodiment of the present disclosure includes:

Step 01, providing target patterns for OPC, selecting a rule in which only one Assist Feature can be added based on a Base AF rule, and establishing an Extra Assist Feature rule.

Specifically, the OPC target patterns in the embodiment includes contact/hole target patterns, the Assist Features in the Base Assist Feature rule and the Extra Assist Feature rule are side bar Assist Features, and the Assist Feature is sub-resolution pattern; wherein the Assist Feature already exists in the OPC target patterns. Firstly, before the Extra Assist Feature rule is established, an initial Rule-based Assist Feature for the OPC target patterns based on the Base Assist Feature rule is established. The initial Rule-based Assist Feature comprises a side bar Assist Feature and a corner bar Assist Feature, and the Assist Feature parameter information is please refer to FIG. 1; then, based on the Base AF rule, selecting a rule in which only one Assist Feature can be added; and establishing an Extra Assist Feature rule (Extra AF rule).

Step 02, making a global size-up of the target patterns target patterns, so that all sides of the target patterns extend outwards by a distance A.

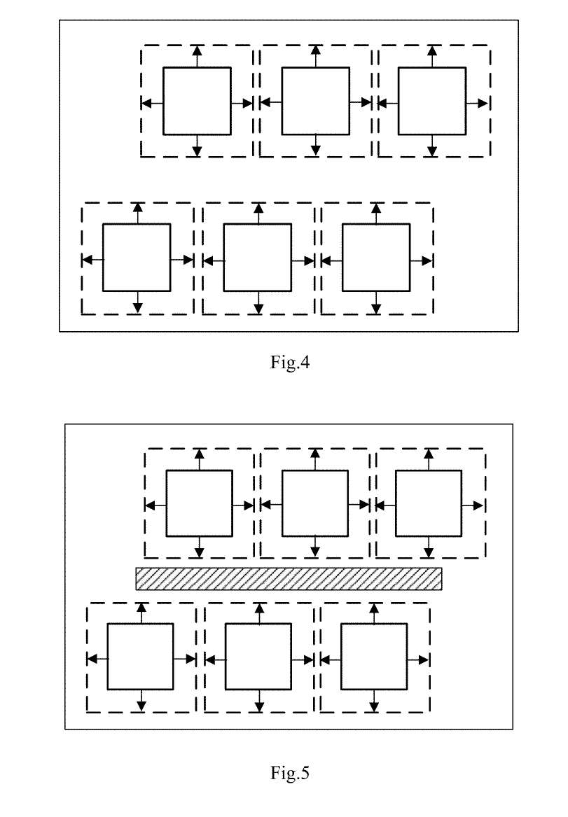

Specifically, as shown in FIG. 4, the contact/hole patterns are globally magnified outwards, so that the four sides of the contact/hole pattern extend outwards by the distance A, less than ½ of the minimum space allowed by the target patterns. It should be noted that the distance A is a non-negative number, and the unit of the distance A is a length unit; in the embodiment, the length unit of the distance A can be nanometer (nm).

Step 03, subtracting the distance value between the corresponding sides of the target patterns formatted under the Extra Assist Feature rule by a distance 2A based on the Extra Assist Feature rule; and carrying out the corresponding adjustment on other parameters which are affected by the overall sizing of the target patterns formatted under the Extra Assist Feature rule based on a distance A.

Specifically, please refer to FIG. 4 again, for the parameter of the distance value between the contact/hole patterns in the specification, which is subtracted by 2A based on the Extra AF rule, and for the other parameters including the distance value between the Assist Feature and the target patterns (S2M), the minimum distance value allowed by the Assist Feature and the target patterns, etc., for example, the parameter of the distance value of the S2M is subtracted by A, the parameter of the minimum distance value allowed by the Assist Feature and the target patterns is subtracted by A.

Step 04, operating the Extra Assist Feature rule to generate a first Assist Feature.

Specifically, please refer to FIG. 5, and an AF has already been added to a region in the target patterns when the overlap edge length between the corresponding sides of the contact/hole patterns is short (indicated by a dotted line).

Step 05, executing the Base AF rule on the target patterns, generating a second Assist Feature by using the first Assist Feature as a newly added reference feature, and superimposing the first Assist Feature, the second Assist Feature and the existing Assist Feature to form a final Assist Feature.

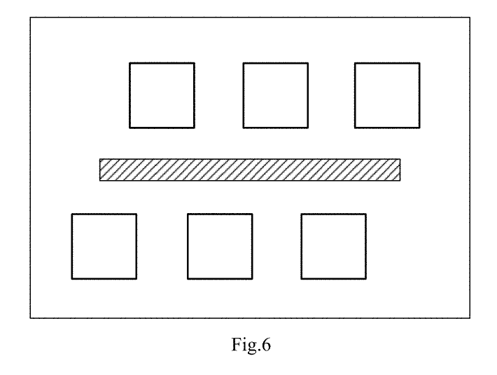

The method according to the present disclosure further comprises a Step between the Step 04 and the Step 05, the Step is, replacing the target patterns after global sizing-up with the target patterns in Step 01, as shown in FIG. 6.

In the Step 05, executing the Base AF rule on the target patterns, generating a second Assist Feature by using the first Assist Feature as a newly-added reference feature, and superimposing the first Assist Feature, the second Assist Feature and the existing Assist Feature to form a final Assist Feature.

Specifically, the first Assist Feature, the initial Rule-based Assist Feature, the original input Assist Feature and the original input reference Assist Feature are used as the reference Feature, the second Assist Feature is generated by executing the Base AF rule on the target patterns; and the final Assist Feature is generated by superimposing the first Assist Feature, the second Assist Feature, the initial Rule-based Assist Feature, and the original input Assist Feature.

While the present disclosure has been particularly shown and described with references to preferred embodiments thereof, if will be understood by those skilled in the art that various changes in form and details may be made herein without departing from the spirit and scope of the present disclosure as defined by the appended claims.

What is claimed is:

1. A method for adding Assist Features, comprising:
Step 01, providing target patterns for OPC, selecting a rule in which only one Assist Feature can be added based on a Base AF rule, and establishing an Extra Assist Feature rule; wherein the target patterns already has Assist Feature;
Step 02, making a global size-up of the target patterns, so that all sides of the target patterns extend outwards by a distance A; wherein the distance A is a non-negative number, and the unit of the distance A is a unit of length;
Step 03, subtracting the distance value between the corresponding sides of the target patterns formatted under the Extra Assist Feature rule by a distance 2A based on the Extra Assist Feature rule; and carrying out the corresponding adjustment on other parameters which are affected by the overall sizing of the target patterns formatted under the Extra Assist Feature rule based on a distance A;
Step 04, operating the Extra Assist Feature rule to generate a first Assist Feature;
Step 05, executing the Base AF rule on the target patterns, generating a second Assist Feature by using the first Assist Feature as a newly added reference feature, and superimposing the first Assist Feature, the second Assist Feature and the existing Assist Feature to form a final Assist Feature.

2. The method for adding Assist Features of claim 1, wherein, in the Step 02, the distance A is less than ½ of the minimum space allowed by the target patterns.

3. The method for adding Assist Features of claim 1, wherein the Assist Features in the Rule-based Assist Feature and the Assist Features in the Extra Assist Feature rule are side bar Assist Features.

4. The method for adding Assist Features of claim 1, wherein, in the Step 01 and before the Extra Assist Feature rule is established, the method further includes: establishing an initial Rule-based Assist Feature on the target patterns based on the Base AF rule; in step 05, the method further comprises: executing the Rule-based Assist Feature on the target patterns, generating a second Assist Feature by using the first Assist Feature, the initial Rule-based Assist Feature, the original input Assist Feature and the original input reference pattern as reference pattern; the final Assist Feature is composed of the first Assist Feature, the second Assist Feature, the initial Rule-based Assist Feature and the original input Assist Feature.

5. The method for adding Assist Features of claim 4, wherein the initial Rule-based Assist Feature comprises side bar Assist Features and corner bar Assist Features.

6. The method for adding Assist Features of claim 1, wherein the target patterns include contact/hole target patterns.

7. The method for adding Assist Features of claim 1, wherein the Assist Feature is sub-resolution pattern.

8. The method for adding Assist Features of claim 1, wherein, further comprises a Step between the Step 04 and the Step 05, the Step is, replacing the target patterns after global sizing-up with the target patterns in Step 01.
